(19) United States
(12) Patent Application Publication
(10) Pub. No.: US 2026/0009157 A1
(43) Pub. Date: Jan. 8, 2026

(54) SiC SUBSTRATE, SiC EPITAXIAL WAFER AND METHOD OF MANUFACTURING SiC DEVICE

(71) Applicant: Resonac Corporation, Tokyo (JP)

(72) Inventors: Yumiko NAKAMURA, Tokyo (JP); Yuzo SASAKI, Tokyo (JP); Yu TAKAHASHI, Tokyo (JP)

(73) Assignee: Resonac Corporation, Tokyo (JP)

(21) Appl. No.: 19/259,079

(22) Filed: Jul. 3, 2025

(30) Foreign Application Priority Data
Jul. 8, 2024 (JP) 2024-109661

(51) Int. Cl. C30B 29/36; H10D 62/832

(52) U.S. Cl. CPC C30B 29/36; H10D 62/8325

(57) ABSTRACT

A SiC substrate according to an embodiment has an end region within 5 mm from an outer circumferential end portion, a density of metallic foreign bodies in the end region detected by a scanning electron microscope is equal to or smaller than 1.5 pieces/mm².

### CROSS-REFERENCE TO RELATED APPLICATION

Priority is claimed on Japanese Patent Application No. 2024-109661, filed Jul. 8, 2024, the content of which is incorporated herein by reference.

### BACKGROUND

### Field

The present disclosure relates to a SiC substrate, a SiC epitaxial wafer and a method of manufacturing a SiC device.

### Description of Related Art

Silicon carbide (SiC) has a dielectric breakdown field slightly larger and a band gap three times larger than those of silicon (Si). In addition, silicon carbide (SiC) has a thermal conductivity about three times higher than that of silicon (Si). For this reason, silicon carbide (SiC) is expected to be used in power devices, high frequency devices, high temperature operation devices, or the like. For this reason, in recent years, SiC epitaxial wafers have been used for the above-mentioned semiconductor devices.

SiC epitaxial wafers are obtained by laminating a SiC epitaxial layer on a surface of a SiC substrate. Hereinafter, a substrate before lamination of the SiC epitaxial layer is referred to as a SiC substrate, and the substrate after lamination of the SiC epitaxial layer is referred to as a SiC epitaxial wafer. The SiC substrate is cut from a SiC ingot. Transistors or interconnections are formed in the SiC epitaxial layer of the SiC epitaxial wafer, and the SiC epitaxial wafer is made into chips to become SiC devices.

The SiC substrate cut from the SiC ingot is subjected to grinding, lapping and polishing to adjust the thickness, parallelism and surface roughness.

Patent Document 1 discloses that a main surface of a SiC substrate on which a SiC epitaxial layer is formed is subjected to chemical mechanical polishing (CMP). Slurry used in the CMP may contain metal oxidant. When cleaning after the CMP is insufficient, the metal oxidant may remain as metal impurities. Patent Document 1 discloses that impurities remaining on the main surface can be removed by cleaning the main surface with aqua regia.

In addition, Patent Document 2 discloses that metal impurities on a main surface of a SiC substrate can cause degradation of electrical characteristics of devices. Patent Document 3 discloses a cleaning method of reducing metal impurities remaining on a main surface of a SiC substrate.

In addition, Patent Document 4 disclosed that an end surface of a SiC substrate is ground to suppress occurrence of edge defects.

### PATENT DOCUMENTS

[Patent Document 1] Japanese Patent No. 7095765
[Patent Document 2] PCT International Publication No. 2020/235225
[Patent Document 3] Japanese Unexamined Patent Application, First Publication No. 2022-51689
[Patent Document 4] Japanese Patent No. 6481790

### SUMMARY

The surface roughness of the epitaxial layer may become locally rough near the outer circumferential end portion of the SiC epitaxial layer. This tendency becomes more significant as the SiC epitaxial layer becomes thicker. This surface roughness can cause defects in the SiC devices. That is, when the surface roughness of the epitaxial layer increases near the outer circumferential end portion, the effective area of the SiC epitaxial wafer becomes smaller.

In consideration of the above-mentioned problems, the present disclosure is directed to providing a SiC substrate and a SiC epitaxial wafer with an end region containing few metallic foreign bodies. In addition, the present disclosure is directed to providing a method of manufacturing a SiC device using the SiC substrate and the SiC epitaxial wafer.

The present invention provides the following means in order to solve the above-mentioned problems.
(1) A SiC substrate according to a first aspect has an end region within 5 mm from an outer circumferential end portion, and a density of metallic foreign bodies in the end region detected by a scanning electron microscope is equal to or smaller than 1.5 pieces/mm².
(2) In the SiC substrate according to the above-mentioned aspect, the density of the metallic foreign bodies in the end region may be equal to or smaller than 1 pieces/mm².
(3) In the SiC substrate according to the above-mentioned aspect, the density of the metallic foreign bodies in the end region may be equal to or smaller than 0.6 pieces/mm².
(4) In the SiC substrate according to the above-mentioned aspect, the density of metallic foreign bodies containing chromium in the metallic foreign bodies in the end region may be equal to or smaller than 0.5 pieces/mm².
(5) In the SiC substrate according to the above-mentioned aspect, the density of metallic foreign bodies containing calcium in the metallic foreign bodies in the end region may be equal to or smaller than 1 pieces/mm².
(6) In the SiC substrate according to the above-mentioned aspect, an average number of the metallic foreign bodies in the end region may be equal to or smaller than three. The average number is an average value of the number of the metallic foreign bodies in each of a first range, a second range and a third range of 0.18 mmx 10 mm in a scanning electron microscope. The first range, the second range and the third range are in a [1-100] direction from a center. Each of the second range and the third range is adjacent to the first range.
(7) In the SiC substrate according to the above-mentioned aspect, the average number in the end region may be equal to or smaller than two.
(8) In the SiC substrate according to the above-mentioned aspect, a diameter may be equal to or greater than 149 mm.
(9) In the SiC substrate according to the above-mentioned aspect, a diameter may be equal to or greater than 199 mm.
(10) The SiC substrate according to the above-mentioned aspect may have a notch cut out toward an inner side of the SiC substrate.
(11) A SiC epitaxial wafer according to a second aspect includes the SiC substrate according to any one of the above-mentioned aspects; and a SiC epitaxial layer formed on one surface of the SiC substrate.
(12) A method of manufacturing a SiC device according to a third aspect has a process of forming a device on the SiC epitaxial layer of the SiC epitaxial wafer according to the above-mentioned aspect.

The SiC substrate according to the above-mentioned aspects has few metallic foreign bodies in the end region, and is less susceptible to surface roughness in the vicinity of the end region of the SiC epitaxial layer. The SiC epitaxial wafer in the above-mentioned aspect has a wide effective area in which a device can be acquired. The method of manufacturing the SiC device according to the above-mentioned aspect can improve acquisition efficiency of high-quality devices.

### BRIEF DESCRIPTION OF THE DRAWINGS

FIG. 1 is a plan view of a SiC substrate according to the embodiment.

FIG. 2 is a photograph of metallic foreign bodies recognized in an end region of the SiC substrate according to the embodiment.

FIG. 3 is a cross-sectional view of the end region of the SiC substrate according to the embodiment.

FIG. 4 is a cross-sectional view of a SiC epitaxial wafer according to the embodiment.

### DETAILED DESCRIPTION

Hereinafter, a SiC substrate or the like according to an embodiment will be described with reference to the accompanying drawings as appropriate. The drawings used in the following description may show enlarged characteristic parts for the sake of convenience in order to make the features of the embodiment easier to understand, and dimensional ratios of each component may differ from the actual ones. The materials, dimensions, or the like, exemplified in the following description are merely examples, and the present invention is not limited to them, and can be modified as appropriate within the scope that does not change the spirit of the invention.

In this specification, an individual direction is indicated by [ ] and a collective direction is indicated by < >. For negative exponents, in crystallography a “-” (bar) is placed above the number, but in this specification, a negative sign is placed before the number.

In addition, in this specification, with reference to a center of the SiC substrate, a [11-20] direction is referred to as a +x direction, a [−1-120] direction is referred to as a −x direction, a [−1100] direction is referred to as a +y direction, a [1-100] direction is referred to as a −y direction, a [0001] direction is referred to as a +z direction, and a [000-1] direction is referred to as a −z direction.

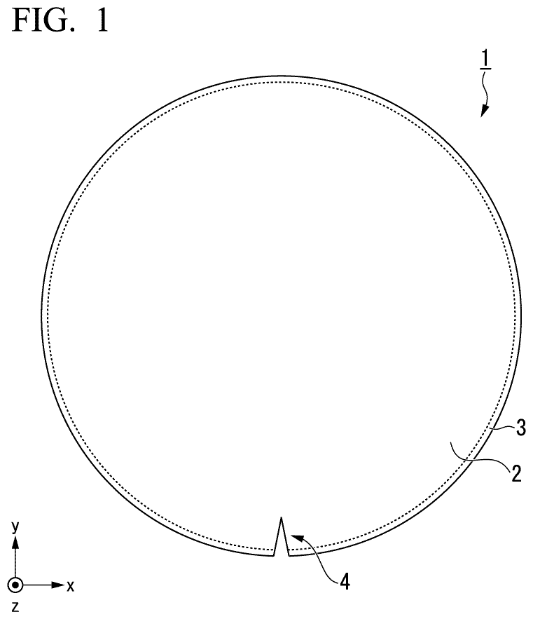

FIG. 1 is a plan view of a SiC substrate 1 according to the embodiment. The SiC substrate 1 is formed of, for example, an n type SiC. A polytype of the SiC substrate 1 is not particularly limited and may be any of 2H, 3C, 4H, and 6H. The SiC substrate 1 is, for example, 4H-SiC.

A plan view shape of the SiC substrate 1 is a substantially circular shape. The SiC substrate 1 may have an orientation flat or a notch 4 to identify a direction of a crystal axis. A diameter of the SiC substrate 1 is equal to or greater than 145 mm, preferably equal to or greater than 149 mm. The diameter of the SiC substrate 1 may be equal to or smaller than 155 mm, preferably equal to or smaller than 151 mm. The diameter of the SiC substrate 1 may be equal to or greater than 195 mm, preferably equal to or greater than 199 mm. The diameter of the SiC substrate 1 may be equal to or smaller than 205 mm, preferably equal to or smaller than 201 mm. The diameter of the SiC substrate 1 may be equal to or greater than 295 mm, preferably equal to or greater than 299 mm. The diameter of the SiC substrate 1 may be equal to or smaller than 305 mm, preferably equal to or smaller than 301 mm.

A plan view shape of the SiC substrate 1 is a substantially circular shape. The SiC substrate has the notch 4 to identify a direction of a crystal axis when seen in the +z direction. The notch 4 is a groove formed by cutting out a part of the SiC substrate 1 inward from an outer circumference of the SiC substrate 1. The notch 4 is located in the −y direction from a center of the SiC substrate 1, for example. The SiC substrate 1 may have an orientation flat instead of the notch 4.

The SiC substrate 1 includes a main region 2, and an end region 3. The main region 2 is a region that constitutes a main surface of the SiC substrate 1, and located inside the end region 3 of the SiC substrate 1. The end region 3 is a region within 5 mm from the outer circumferential end portion of the SiC substrate 1. The end region 3 includes an edge exclusion region. The edge exclusion region is a region of the SiC substrate 1 that is excluded from an acquisition region of the SiC device. The end region 3 and the edge exclusion region do not necessarily coincide with each other, and it is preferable that the edge exclusion region is narrower than the end region 3.

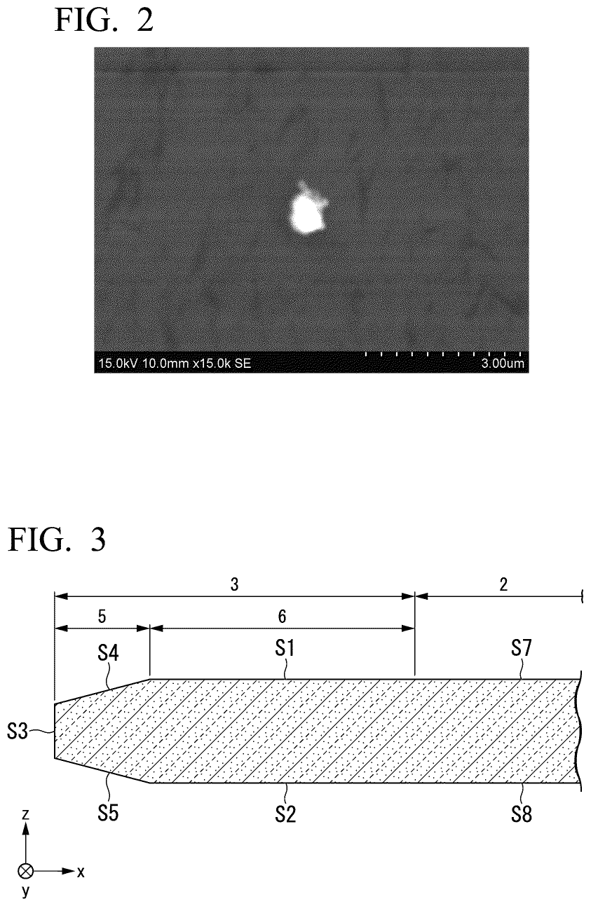

The end region 3 may contain metallic foreign bodies. The metallic foreign bodies cause abnormal growth during the crystal growth of the SiC epitaxial layer on the SiC substrate 1. FIG. 2 is a photograph of metallic foreign bodies recognized in the end region 3.

The metallic foreign bodies can be observed by a scanning electron microscope (SEM). The scanning electron microscope is, for example, a JSM-IT510 manufactured by JEOL Ltd. As shown in FIG. 2, the metallic foreign bodies are areas that have higher contrast than the surrounding area and are observed as white spots. In addition, the white spots identified in the SEM images can be determined to be metallic foreign bodies using an energy dispersive X-ray analyzer (EDX). The EDX is capable of elemental analysis and is attached to the SEM. The metallic foreign bodies contain, for example, Na, Ca, Fe, Cr, Ni, or Cu.

A density of the metallic foreign bodies in the end region 3 is equal to or smaller than 1.5 pieces/mm², preferably equal to or smaller than 1 pieces/mm², more preferably equal to or smaller than 0.6 pieces/mm². The density of the metallic foreign bodies in the end region 3 may be 0 pieces/mm². The metallic foreign bodies in the end region 3 can be reduced by polishing the outer circumference of the SiC substrate 1 and then cleaning the outer circumference of the SiC substrate 1 with a predetermined cleaning solution. When the density of the metallic foreign bodies in the end region 3 is low, an abnormal growth of the SiC epitaxial layer can be suppressed.

The density of the metallic foreign bodies in the end region 3 is obtained by the following procedure. First, a position of the end region 3 opposite to the notch 4 with reference to the center of the SiC substrate 1 (i.e., a position in the +y direction from the center of the SiC substrate 1) is observed by the SEM. The observation point is an arbitrary position in the end region 3 with a width of 5 mm. The observation is performed within a range of 0.18 mmx 10 mm. This range is all estimated using the SEM. The density of the metallic foreign bodies in the predetermined range can be calculated by dividing the number of the metallic foreign bodies measured within the range by the area of the range. The density of the metallic foreign bodies in each of the three ranges (first range, second range, third range) adjacent to the x direction is calculated, and the average value of these is regarded as the density of the metallic foreign bodies in the end region 3. The SiC substrate 1 is polished while being rotated. For this reason, the density measurements of the metallic foreign bodies at the predetermined positions in the end region 3 did not differ significantly from the average value for the entire end region 3.

The density of the metallic foreign bodies containing chromium (Cr) in the end region 3 is preferably equal to or smaller than 0.5 pieces/mm², more preferably equal to or smaller than 0.3 pieces/mm², and even more preferably equal to or smaller than 0.1 pieces/mm². The density of the metallic foreign bodies containing chromium in the end region 3 may be 0 pieces/mm².

In addition, the density of the metallic foreign bodies containing calcium (Ca) in the end region 3 is preferably equal to or smaller than 1 pieces/mm², more preferably equal to or smaller than 0.3 pieces/mm², and even more preferably 0.1 pieces/mm². The density of the metallic foreign bodies containing calcium in the end region 3 may be 0 pieces/mm².

The densities of the metallic foreign bodies containing chromium and the metallic foreign bodies containing calcium can be determined using the same procedure as for the density of the entire metallic foreign bodies. The metallic foreign bodies containing chromium or calcium can be extracted using the EDX.

The metallic foreign bodies including chromium can reduce the carrier life and other characteristics of the SiC device when incorporated into the SiC epitaxial film. The metallic foreign bodies containing chromium are one of the reasons why the SiC device does not exhibit properties close to their theoretical values. In addition, the metallic foreign bodies containing calcium can cause degradation of the oxide film formed during fabrication of the SiC device. The metallic foreign bodies containing calcium can cause deterioration of the oxide film. For this reason, these SiC substrates, which contain few metallic foreign bodies, are of high quality.

In addition, an average number of the metallic foreign bodies in the end region 3 is, for example, three, preferably two, and more preferably one or less. The average number of the metallic foreign bodies is an average value of numbers of the metallic foreign bodies in the first range, the second range and the third range of the scanning electron microscope. The average number of the metallic foreign bodies is obtained by dividing the total number of the metallic foreign bodies in the first range, the second range and the third range by a range number. The first, second and third ranges for counting the number of metallic foreign bodies are the same as the ranges used to calculate the density of the metallic foreign bodies. The first, second and third ranges are in the +y direction from the center. Each of the second range and the third range is adjacent to the first range.

FIG. 3 is a cross-sectional view of the end region 3 of the SiC substrate of the SiC substrate 1 according to the embodiment. The end region 3 has, for example, a bevel portion 5, and a flat portion 6. The bevel portion 5 is located on the outer circumferential side of the end region 3 and is formed by rounding off the corners of the end portion of the SiC substrate 1. A width of the bevel portion 5 in the radial direction may be, for example, 76 μm or more and 508 μm or less. The bevel portion 5 prevents the SiC substrate 1 from cracking or chipping. The flat portion 6 is a portion of the end region 3 that is located more inwardly of the SiC substrate 1 than the bevel portion 5.

A first main surface S1 of the flat portion 6 is continuous with a first main surface S7 of the main region 2. The first main surface S7 of the main region 2 is one surface of the SiC substrate 1. The first main surface S1 and the first main surface S7 are, for example, Si surfaces. For example, the SiC epitaxial layer can be formed on the first main surface S1 and the first main surface S7, and the device can be formed on the SiC epitaxial layer. The surface roughness of each of the first main surface S1 and the first main surface S7 is equal to or smaller than 0.1 nm. The surface roughness is, arithmetic mean roughness (Ra). The surface roughness can be measured by a laser microscope (for example, OPTELICS HYBRID+ manufactured by Lasertec Corporation). This is also the same as for a second main surface S2, an end surface S3, a first chamfer surface S4, and a second chamfer surface S5, which will be described below.

The second main surface S2 of the flat portion 6 is continuous with a second main surface S8 of the main region 2. The second main surface S8 of the main region 2 is one surface of the SiC substrate 1. The second main surface S2 and the second main surface S8 are, for example, C surfaces. The surface roughness of each of the second main surface S2 and the second main surface S8 is equal to or smaller than 0.5 nm.

The bevel portion 5 has, for example, the end surface S3, the first chamfer surface S4, and the second chamfer surface S5. The bevel portion 5 may be a curved surface connecting the first main surface S1 and the second main surface S2.

The end surface S3 is a surface that forms the outermost circumference of the SiC substrate 1. The end surface S3 has a surface roughness greater than that of the first main surface S1 and the second main surface S2. In particular, the end surface S3 forming the notch 4 has a surface roughness greater than that of the first main surface S1 and the second main surface S2, and has a surface roughness greater than that of the end surface S3 other than the notch 4. The surface roughness of the end surface S3 is, for example, equal to or smaller than 20 nm, preferably equal to or smaller than 15 nm, and even more preferably equal to or smaller than 10 nm, and even further preferably equal to or smaller than 6 nm. The surface roughness of the end surface S3 is, for example, equal to or greater than 1 nm. The surface roughness of the end surface S3 is an average value of a surface roughness at each of a first measurement point in the +x direction from the center of the SiC substrate 1, a second measurement point in the −x direction from the center of the SiC substrate 1, a third measurement point in the +y direction from the center of the SiC substrate 1, and a fourth measurement point in the −y direction from the center of the SiC substrate 1.

The first chamfer surface S4 is a surface that connects one side of the end surface S3 and one side of the first main surface S1. While the first chamfer surface S4 shown in FIG. 3 is an inclined surface, the first chamfer surface S4 may be a curved surface. The first chamfer surface S4 has a surface roughness greater than that of the first main surface S1. In particular, the first chamfer surface S4 forming the notch 4 has a surface roughness greater than that of the first main surface S1 and greater than that of the first chamfer surface S4 other than the notch 4. The surface roughness of the first chamfer surface S4 is, for example, preferably equal to or smaller than 15 nm, more preferably equal to or smaller than 10 nm, further more preferably equal to or smaller than 8 nm, and particularly preferably equal to or smaller than 6 nm. The surface roughness of the first chamfer surface S4 may be, for example, equal to or greater than 1 nm. The surface roughness of the first chamfer surface S4 is an average value of the first measurement point, the second measurement point, the third measurement point and the fourth measurement point.

The second chamfer surface S5 is a surface connecting one side of the end surface S3 and one side of the second main surface S2. While the second chamfer surface S5 shown in FIG. 3 is the inclined surface, the second chamfer surface S5 may be a curved surface. The second chamfer surface S5 has a surface roughness greater than that of the second main surface S2. In particular, the second chamfer surface S5 forming the notch 4 has a surface roughness greater than that of the second main surface S2, and a surface roughness greater than that of the second chamfer surface S5 other than the notch 4. The surface roughness of the second chamfer surface S5 is, for example, preferably equal to or smaller than 15 nm, more preferably equal to or smaller than 10 nm, further more preferably equal to or smaller than 8 nm, and particularly preferably equal to or smaller than 6 nm. The surface roughness of the second chamfer surface S5 may be, for example, equal to or greater than 1 nm. The surface roughness of the second chamfer surface S5 is an average value of the first measurement point, the second measurement point, the third measurement point and the fourth measurement point.

It is preferable that the main region 2 does not contain metallic foreign bodies. The main region 2 may contain metallic foreign bodies with a lower density than the end region 3. The density of the metallic foreign bodies in the main region 2 is equal to or smaller than 0.007 pieces/mm², and preferably equal to or smaller than 0.003 pieces/mm². The density of the metallic foreign bodies in the main region 2 is determined by observing three fields of view at a distance of half the radius in the +y direction from the center of the SiC substrate 1 using the SEM. The method of determining the density of the metallic foreign bodies is the same as in the end region 3.

The estimation/observation of the SiC substrate 1 is preferably performed under a clean environment. For example, the SiC substrate 1 after cleaning is introduced into a wafer case in a clean room and packed together with the wafer case. By transporting the SiC substrate 1 in this state, it is possible to prevent foreign substances and the like from adhering to the SiC substrate 1 during transport. When the SiC substrate 1 is estimated and observed, in the clean room, the SiC substrate 1 is removed from the wafer case and estimation/observation of the SiC substrate 1 is performed. There is no significant difference in the estimation/observation results between the SiC substrate 1 immediately after cleaning and the SiC substrate 1 transported using the above procedure and removed from the clean room.

An example of a method of manufacturing the SiC substrate 1 according to the embodiment will be described. The method of manufacturing the SiC substrate 1 according to the embodiment has an edge polishing process, a first cleaning process, a main surface polishing process, and a second cleaning process.

First, a SiC ingot is sliced. An outer circumferential portion of the sliced substrate is chamfered to obtain the SiC substrate 1 having the bevel portion 5 formed.

Next, after grinding the bevel portion 5, the edge polishing process is carried out. The edge polishing can be either slurry polishing using a slurry or tape polishing using a wrapping film.

For example, when the first chamfer surface S4 and the second chamfer surface S5 are polished with the slurry, a polishing pad hits the first chamfer surface S4 or the second chamfer surface S5 while applying the slurry. For example, a cylinder is pressurized so that the first chamfer surface S4 of the SiC substrate 1, which is vacuum-absorbed, abuts against the polishing pad, and the first chamfer surface S4 is polished. A rotation number of the polishing pad is, for example, 200 rpm or more and 400 rpm or less. The rotation number of the SiC substrate 1 is, for example, 5 rpm or more and 30 rpm or less. A load of the polishing pad with respect to the SiC substrate 1 is 5 kg or more and 30 kg or less. A polishing time is, for example, 15 minutes.

In addition, for example, when the end surface S3 is polished with the slurry, the polishing pad hits the end surface S3 while applying the slurry. The polishing pads are attached to drums arranged in four sections around the SiC substrate 1, which is vacuum-adsorbed. By rotating the drum and the SiC substrate, the SiC substrate 1 comes into contact with the polishing pad by a centrifugal force, and the end surface S3 is polished. The rotation number of the drum is, for example, 200 rpm or more and 400 rpm or less. The rotation number of the SiC substrate 1 is, for example, 5 rpm or more and 30 rpm or less. A polishing time is, for example, 15 minutes.

The notch 4 is difficult to grind at the end portion. The notch 4 is polished using a low-grit grindstone. For example, the notch 4 is polished by pressing a disc-shaped polishing pad against the notch 4 while rotating it. A rotation number of the polishing pad is, for example, 10000 rpm or more and 15000 rpm or less. The load for pressing the polishing pad against the notch 4 is, for example, 5 kg or more and 30 kg or less. A polishing time is, for example, 5 minutes.

A polishing agent used for polishing includes, for example, colloidal silica, aluminum oxide, diamond, or the like. The polishing agent includes metal impurities as oxidizing agents. The metal impurities are thought to be a cause of the metallic foreign bodies.

It is preferable to polish the bevel portion 5 in multiple stages by varying the size of the abrasive grain. For example, after polishing with diamond abrasive grains with a median diameter (D50) of 10 μm, polishing with diamond abrasive grains with a median diameter (D50) of 5 μm is performed, and finish polishing with diamond abrasive grains with a median diameter (D50) of 1 μm is further performed. After polishing, the surface roughness of the first chamfer surface S4, the second chamfer surface S5 and the end surface S3 is 1 nm or more and 15 nm or less.

Next, after the edge polishing process, the first cleaning process is performed. In the first cleaning process, the SiC substrate 1 is cleaned with ultrasonic waves using a predetermined cleaning solution. The predetermined cleaning solution is a combination of acid and a chelating agent. The acid is hydrochloric acid or oxalic acid. The chelating agent is, for example, ethylenediaminetetraacetic acid. Since the cleaning solution does not contain hydrogen peroxide, the SiC substrate 1 is not over-etched. For this reason, the surface roughness of the SiC substrate is hardly affected by this cleaning.

Once the metallic foreign bodies dry, they adhere to the SiC substrate 1 and become difficult to remove. Before the metallic foreign bodies are fixed to the SiC substrate 1, the width of the metallic foreign bodies in the end region 3 can be significantly reduced by cleaning with a cleaning solution in the first cleaning process. In addition, the chelating agent contained in the cleaning solution prevents the metallic foreign bodies from reattaching. Further, since cleaning after the main surface polishing (described later) is performed with a cleaning solution, the first cleaning process is performed with pure water in general, however, in this embodiment, the cleaning solution is used to remove the metallic foreign bodies in the end region 3.

The ultrasonic wave cleaning is performed in the high frequency band, for example, 200 kHz or more and 500 kHz or less. The ultrasonic wave cleaning may be performed by combining a high frequency band with a frequency band called megasonic, which is 1 MHz or more and 2 MHz or less. The ultrasonic wave cleaning for each frequency band is performed for 10 minutes or more. The ultrasonic wave cleaning of each frequency band may be performed multiple times, for example, for 10 minutes each.

Next, the main surface polishing process is performed. In the main surface polishing process, the main surface of the SiC substrate 1 is polished. The main surface of the SiC substrate 1 is polished by, for example, CMP. The SiC substrate 1 may be polished on one side or double sides. For example, in the case of the one side polishing, the one surface of the SiC substrate 1 is attached to the pressure head, and the other surface of the SiC substrate 1 is pressed against a polishing cloth. The SiC substrate 1 is rotated while a polishing agent is supplied to the polishing cloth. The SiC substrate 1 may be rotated while revolving relative to the pressure head. The rotation directions of revolution and rotation can be the same or opposite. The polishing agent is the same as in the edge polishing process.

Next, the second cleaning process is performed. In the second cleaning process, the SiC substrate 1 after the main surface polishing is cleaned. The cleaning is performed by immersing the substrate in the cleaning solution that fills a cleaning tank. The cleaning solution is filtered through a filter and circulated by a pump. A temperature of the cleaning solution is controlled. The temperature of the cleaning solution is, for example, 50° C. The ultrasonic wave cleaning is also possible during the second cleaning process.

In the second cleaning process, the acid cleaning is performed using ultrasonic waves of a plurality of frequencies. In addition, alkali cleaning may be performed before the acid cleaning. The acid cleaning is performed using the same cleaning solution as in the first cleaning process. The alkali cleaning is performed using, for example, potassium hydroxide and surfactant. When the alkali cleaning is performed, a portion of the abrasive grains and organic matters attached to the SiC substrate 1 is removed. The alkali cleaning is performed at room temperature for 10 minutes or more, for example. After the acid cleaning and alkali cleaning, pure water cleaning may be performed.

The SiC substrate 1 according to the embodiment can be fabricated by the above-mentioned procedure. By performing the edge polishing process and the first cleaning process, it is possible to suppress the adhesion of the metallic foreign bodies to the end region 3. In addition, in the first cleaning process and the second cleaning process, by not performing the RCA cleaning, the SiC substrate 1 can be prevented from being etched during cleaning, which would cause the surface roughness of the SiC substrate 1 to increase. Further, the RCA cleaning is a cleaning method using hydrogen peroxide.

In the SiC substrate 1 of the embodiment, the density of the metallic foreign bodies contained in the end region 3 is equal to or less than the predetermined value. Since there are few metallic foreign bodies in the end region 3, the abnormal growth of the SiC epitaxial layer in the vicinity of the end region 3 can be suppressed. As a result, the SiC substrate 1 of the embodiment is less susceptible to localized surface roughness in the SiC epitaxial layer. The SiC substrate 1 of the embodiment has a large effective area that can be used for acquisition of the SiC devices.

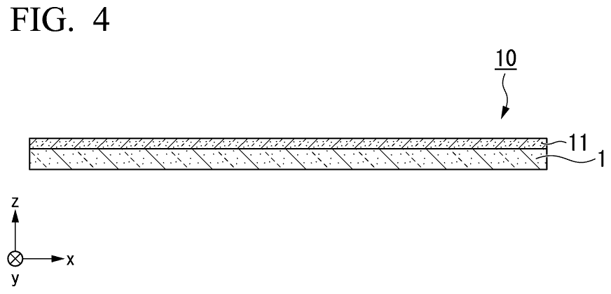

FIG. 4 is a cross-sectional view of a SiC epitaxial wafer 10 according to the embodiment. The SiC epitaxial wafer 10 is fabricated by forming a SiC epitaxial layer 11 on the SiC substrate 1 according to the embodiment. The SiC epitaxial wafer 10 shown in FIG. 4 includes the SiC substrate 1, and the SiC epitaxial layer 11, which are described above. The SiC substrate 1 has few metallic foreign bodies in the end region 3, so the local surface roughness of the SiC epitaxial layer 11 is suppressed. The thickness of the SiC epitaxial layer 11 is, for example, from 1 μm to 100 μm. Since the surface roughness increases as the thickness of the SiC epitaxial layer 11 increases, the effect of the present disclosure is remarkable when the thickness of the SiC epitaxial layer 11 is 25 μm or more.

The SiC device can be acquired, for example, from the SiC epitaxial wafer 10 shown in FIG. 4. The SiC device can be fabricated by forming elements such as transistors on the SiC epitaxial layer 11 of the SiC epitaxial wafer 10 and then forming them into a chip. The SiC epitaxial wafer 10 is divided into rectangles, and an element is formed on each rectangle to create the SiC device. The SiC device may be fabricated by forming elements such as transistors on the SiC epitaxial wafer 10 after chipping the SiC epitaxial wafer 10. The SiC device includes a chipped SiC substrate and a SiC epitaxial layer on one surface of the chipped SiC substrate with an element formed therein.

Although the preferred embodiment of the present invention has been described in detail above, the present invention is not limited to the specific embodiment, and various modifications and alterations are possible within the scope of the spirit of the present invention described in the claims.

### EXAMPLES

### Example 1

A SiC substrate with an off angle of 4° and measuring 8 inches was prepared. First, the outer circumferential end portion of the SiC substrate was subjected to outer circumference grinding using a #600 polishing grindstone. Next, the outer circumferential end portion of the SiC substrate was edge-polished using slurry. In addition, a notch portion of the SiC substrate was polished with the grindstone.

The slurry polishing was carried out in three stages by changing the median diameter of the abrasive grains (diamond abrasive grains) of the polishing agent. The median diameter of the abrasive grains in the first stage was 10 μm, that in the second stage was 5 μm, and that in the third stage was 1 μm. After each of the first, second, and third stages of polishing, the surface roughness of the first chamfer surface S4, the end surface S3, and the second chamfer surface S5 were measured. The surface roughness was measured using OPTELICS HYBRID+ manufactured by Lasertec Corporation. The measurement results are shown in the following Table 1. In Table 1, the measurement results before polishing are also referred to as “an initial stage.”

TABLE 1

Surface roughness (mm)

| | First | Second | Third | Initial |
|---|---|---|---|---|
| | stage | stage | stage | stage |
| First chamfer surface | 6 | 6 | 5 | 97 |
| End surface | 15 | 9 | 6 | 189 |
| Second chamfer surface | 10 | 5 | 8 | 89 |

Next, after edge polishing, the SiC substrate was subjected to ultrasonic wave cleaning using a mixed liquid of hydrochloric acid and ethylenediaminetetraacetic acid. The temperature of the cleaning solution was 50° C. The ultrasonic wave cleaning was performed in two separate steps. The first ultrasonic wave cleaning was performed using ultrasonic waves in the high frequency band of 200 kHz or more and 500 kHz or less. In addition, the frequency of the ultrasonic wave was not kept constant within this frequency band, but was changed periodically. The second ultrasonic wave cleaning was performed using ultrasonic waves with a frequency of 1 MHz or more and 2 MHz or less, known as megasonics. A time for each ultrasonic wave cleaning was 10 minutes.

Next, double sides of the SiC substrate are polished using colloidal silica as a polishing agent through CMP.

Next, after polishing, the SiC substrate was subjected to alkali cleaning. The alkali cleaning was performed at a room temperature for 10 minutes using potassium hydroxide and sodium alkyl ether sulfate. The SiC substrate was then subjected to ultrasonic wave cleaning using a mixed liquid of hydrochloric acid and ethylenediaminetetraacetic acid. The cleaning condition is the same as cleaning condition after edge polishing.

Then, after cleaning, the SiC substrate was taken out and dried. Next, the end region of the SiC substrate was observed by the SEM. The observation point was set to the end region 3, located in the +y direction from the center of the SiC substrate 1. Neighboring three ranges were measured within a range of 0.18 mm×10 mm. Then, the density of the metallic foreign bodies in the end region was obtained. In addition, the average number of the metallic foreign bodies in the three ranges of the end region 3 was obtained.

### Comparative Example 1

Comparative Example 1 is distinguished from Example 1 in that the edge polishing and the first cleaning process were not performed. The other conditions were the same as in Example 1.

### Comparative Example 2

Comparative Example 2 is distinguished from Example 1 in that the edge polishing and the first cleaning process were not performed and the RCA cleaning in the second cleaning process was performed. The RCA cleaning was performed using a mixed liquid of 98% sulfuric acid and 30% hydrogen peroxide in a 1:1 ratio. Sulfuric acid/hydrogen peroxide washing was performed at 100° C. for 10 minutes. The other conditions were the same as in Example 1.

The following Table 2 summarizes the densities of the metallic foreign bodies in the end regions of Example 1, Comparative Example 1 and Comparative Example 2. Further, the notation of Fe and Cr indicates that both Fe and Cr peaks were detected within one foreign substance.

TABLE 2

| | | | Densities of three ranges | | | | | |
|---|---|---|---|---|---|---|---|---|
| | RCA | Edge | (pieces/mm²) | | | | | |
| | cleaning | polishing | Na | Ca | Fe | Fe, Cr | Ni | Sum |
| Example 1 | None | Exist | 0.00 | 0.00 | 0.37 | 0.00 | 0.00 | 0.56 |
| Comparative | None | None | 0.93 | 1.48 | 0.56 | 0.56 | 0.37 | 3.33 |
| Example 1 | | | | | | | | |
| Comparative | Exist | None | 0.00 | 1.11 | 0.00 | 0.74 | 0.00 | 1.85 |
| Example 2 | | | | | | | | |

In addition, the following Table 3 summarizes the average numbers of the metallic foreign bodies in three ranges of the end regions of Example 1, Comparative Example 1 and Comparative Example 2.

TABLE 3

| | RCA | Edge | Average number of three ranges | | | | | |
|---|---|---|---|---|---|---|---|---|
| | cleaning | polishing | Na | Ca | Fe | Fe, Cr | Ni | Sum |
| Example 1 | None | Exist | 0.0 | 0.0 | 0.7 | 0.0 | 0.0 | 1.0 |
| Comparative | None | None | 1.7 | 2.7 | 1.0 | 1.0 | 0.7 | 6.0 |
| Example 1 | | | | | | | | |
| Comparative | Exist | None | 0.0 | 2.0 | 0.0 | 1.3 | 0.0 | 3.3 |
| Example 2 | | | | | | | | |

In addition, the following Table 4 summarizes the total numbers of the metallic foreign bodies in the entire range of the end region (entire circumference of the substrate) for Example 1, Comparative Example 1 and Comparative Example 2.

TABLE 4

| | RCA | Edge | Total number/8-inch substrate | | | | | |
|---|---|---|---|---|---|---|---|---|
| | cleaning | polishing | Na | Ca | Fe | Fe, Cr | Ni | Sum |
| Example 1 | None | Exist | 0 | 0 | 21 | 0 | 0 | 31 |
| Comparative | None | None | 52 | 84 | 31 | 31 | 21 | 188 |
| Example 1 | | | | | | | | |
| Comparative | Exist | None | 0 | 63 | 0 | 42 | 0 | 105 |
| Example 2 | | | | | | | | |

### Example 2

Example 2 is distinguished from Example 1 in that a 6-inch SiC substrate was used. The other conditions were the same as in Example 1.

### Comparative Example 3

Comparative Example 3 is distinguished from Comparative Example 1 in that a 6-inch SiC substrate was used. The other conditions are the same as in Comparative Example 1.

### Comparative Example 4

Comparative Example 4 is distinguished from Comparative Example 2 in that a 6-inch SiC substrate was used. The other conditions are the same as in Comparative Example 2.

In addition, the following Table 5 summarizes the total numbers of the metallic foreign bodies in the entire range of the end region (entire circumference of the substrate) for Example 2, Comparative Example 3 and Comparative Example 4. Further, the average numbers of the metallic foreign bodies in the three ranges of Example 2, Comparative Example 3 and Comparative Example 4 were the same as those of Example 1, Comparative Example 1 and Comparative Example 2, respectively.

TABLE 5

| | RCA | Edge | Total number/6-inch substrate | | | | | |
|---|---|---|---|---|---|---|---|---|
| | cleaning | polishing | Na | Ca | Fe | Fe, Cr | Ni | Sum |
| Example 2 | None | Exist | 0 | 0 | 16 | 0 | 0 | 24 |
| Comparative | None | None | 39 | 63 | 24 | 24 | 16 | 141 |
| Example 3 | | | | | | | | |
| Comparative | Exist | None | 0 | 47 | 0 | 31 | 0 | 79 |
| Example 4 | | | | | | | | |

As shown in Tables 2 to 5, cleaning with a predetermined cleaning solution after edge polishing was able to reduce the metallic foreign bodies in the end region. In addition, the reduction in metallic foreign bodies was greater than that achieved by the RCA cleaning. The metallic foreign bodies were adhered to the SiC substrate, and it is thought that the RCA cleaning alone could not sufficiently remove them.

### EXPLANATION OF REFERENCES

1 SiC substrate
2 Main region
3 End region
4 Notch
5 Bevel portion
6 Flat portion
10 SiC epitaxial wafer
11 SiC epitaxial layer
S1, S7 First main surface
S2, S8 Second main surface
S3 End surface
S4 First chamfer surface
S5 Second chamfer surface

1. A SiC substrate having an end region within 5 mm from an outer circumferential end portion, wherein a density of metallic foreign bodies in the end region detected by a scanning electron microscope is equal to or smaller than 1.5 pieces/mm².

2. The SiC substrate according to claim 1, wherein the density of the metallic foreign bodies in the end region is equal to or smaller than 1 pieces/mm².

3. The SiC substrate according to claim 1, wherein the density of the metallic foreign bodies in the end region is equal to or smaller than 0.6 pieces/mm².

4. The SiC substrate according to claim 1, wherein the density of metallic foreign bodies containing chromium in the metallic foreign bodies in the end region is equal to or smaller than 0.5 pieces/mm².

5. The SiC substrate according to claim 1, wherein the density of metallic foreign bodies containing calcium in the metallic foreign bodies in the end region is equal to or smaller than 1 pieces/mm².

6. The SiC substrate according to claim 1, wherein an average number of the metallic foreign bodies in the end region is equal to or smaller than three,
the average number is an average value of the number of the metallic foreign bodies in each of a first range, a second range and a third range of 0.18 mm×10 mm in a scanning electron microscope,
the first range, the second range and the third range are in a [1-100] direction from a center, and
each of the second range and the third range is adjacent to the first range.

7. The SiC substrate according to claim 6, wherein the average number in the end region is equal to or smaller than two.

8. The SiC substrate according to claim 1, wherein a diameter is equal to or greater than 149 mm.

9. The SiC substrate according to claim 1, wherein a diameter is equal to or greater than 199 mm.

10. The SiC substrate according to claim 1, having a notch cut out toward an inside of the SiC substrate.

11. A SiC epitaxial wafer comprising:
the SiC substrate according to claim 1; and
a SiC epitaxial layer formed on one surface of the SiC substrate.

12. A method of manufacturing a SiC device, having a process of forming a device on the SiC epitaxial layer of the SiC epitaxial wafer according to claim 11.
